(19) United States
(12) Patent Application Publication
(10) Pub. No.: US 2025/0357082 A1
(43) Pub. Date: Nov. 20, 2025

(54) PLASMA PROCESSING APPARATUS AND PLASMA PROCESSING METHOD

(71) Applicant: Tokyo Electron Limited, Tokyo (JP)

(72) Inventors: Toshiharu WADA, Gyeonggi-do (KR); Shun ITOH, Miyagi (JP)

(73) Assignee: Tokyo Electron Limited, Tokyo (JP)

(21) Appl. No.: 19/291,652

(22) Filed: Aug. 6, 2025

Related U.S. Application Data
(63) Continuation of application No. PCT/JP2024/005252, filed on Feb. 15, 2024.

(30) Foreign Application Priority Data
Feb. 17, 2023 (JP) 2023-023534

(51) Int. Cl. H01J 37/32

(52) U.S. Cl. CPC H01J 37/32174; H01J 37/32146; H01J 2237/3341

(57) ABSTRACT

A plasma processing apparatus includes a chamber, a substrate support, a gas supply, a first power supply, a second power supply and circuitry in which the circuitry executes plasma processing in which a cycle including a first period, a second period, a third period, and a fourth period in this order is repeated, controls the first power supply such that a source RF signal has a first power level in the first period, has a second power level that is smaller than the first power level and larger than a zero power level in the second period, and controls the second power supply such that a bias signal has a fifth power level that is larger than the zero power level in the second period, and has a sixth power level that is larger than the fifth power level in the fourth period.

### CROSS-REFERENCE TO RELATED APPLICATIONS

This application is a bypass continuation application of international application No. PCT/JP2024/005252 having an international filing date of Feb. 15, 2024 and designating the United States, the international application being based upon and claiming the benefit of priority from Japanese Patent Application No. 2023-023534, filed on Feb. 17, 2023, the entire contents of each are incorporated herein by reference.

### BACKGROUND

### Field

An exemplary embodiment of the present disclosure relates to a plasma processing apparatus and a plasma processing method.

### Description of Related Art

Japanese Patent Application Laid-Open No. 2015-173240 discloses a technique for etching a region made of silicon oxide.

### SUMMARY

A plasma processing apparatus in one exemplary embodiment of the present disclosure includes a chamber; a substrate support that is disposed in the chamber; a gas supply configured to supply a processing gas into the chamber; a first power supply configured to supply a source RF signal to the chamber to form plasma from the processing gas in the chamber; a second power supply configured to supply a bias signal to the substrate support; and a controller, in which the controller executes plasma processing in which a cycle including a first period, a second period, a third period, and a fourth period in this order is repeated, controls the first power supply such that the source RF signal has a first power level in the first period, has a second power level that is smaller than the first power level and larger than a zero power level in the second period, has a third power level that is smaller than the first power level and larger than the zero power level in the third period, and has a fourth power level that is smaller than the first power level and larger than the zero power level in the fourth period, and controls the second power supply such that the bias signal has a fifth power level that is larger than the zero power level in the second period, and has a sixth power level that is larger than the fifth power level in the fourth period.

### BRIEF DESCRIPTION OF DRAWINGS

The scope of the present disclosure is best understood from the following detailed description of exemplary embodiments when read in conjunction with the accompanying drawings.

FIG. 1 is a diagram for describing a configuration example of a plasma processing system.

FIG. 2 is a diagram for describing a configuration example of a capacitively coupled plasma processing apparatus.

FIG. 3 is a diagram for describing a configuration of a plasma processing apparatus in an embodiment.

FIG. 4 is a diagram illustrating an example of supply of a source RF signal and a bias RF signal in each cycle.

FIG. 5 is an explanatory view describing an example of a film on a substrate before etching processing.

FIG. 6 is an explanatory view describing an example of a state of a film on a substrate in a first period, a second period, a third period, and a fourth period.

FIG. 7 is an explanatory view describing an example of the film on the substrate after the etching processing.

FIG. 8 is a numerical expression describing a relationship between an incidence angle θ of ions into the film on the substrate and a temperature Ti of the ions.

FIG. 9 is a graph illustrating a result of comparison between a ratio of C—C bonds (carbon bonds) in a protective film on a mask in a case where a bias RF signal is supplied to a substrate support and a ratio of C—C bonds in the protective film on a mask in a case where the bias RF signal is not supplied to the substrate support, in the second period.

FIG. 10 is a graph illustrating a result of verifying a relationship between the ratio of C—C bonds in the protective film on the mask and an amount of a loss of the protective film by etching.

FIG. 11 is a graph illustrating a result of comparison between a line width roughness of a finally formed film in a case where the bias RF signal is supplied to the substrate support and a line width roughness of a finally formed film in a case where the bias RF signal is not supplied to the substrate support, in the second period.

FIG. 12 is a diagram illustrating a result of measuring a shape of the finally formed film in a case where the bias RF signal is not supplied to the substrate support and a shape of the finally formed film in a case where the bias RF signal is supplied to the substrate support, in the third period.

FIG. 13 is a graph illustrating a result of comparison of the ratio of C—C bonds in the protective film on the mask in a case where a temperature of the substrate support is set to 130° C. and 155° C.

FIG. 14 is a diagram for describing a configuration of the plasma processing apparatus in a case where a voltage pulse signal is used as a bias signal.

FIG. 15 is a diagram illustrating an example of supply of the source RF signal and the voltage pulse signal in each cycle.

FIG. 16 is a diagram for describing a configuration of the plasma processing apparatus in a case where an upper DC signal is supplied to an upper electrode.

### DETAILED DESCRIPTION

Hereinafter, each embodiment of the present disclosure will be described.

In an exemplary embodiment, a plasma processing apparatus is provided, including a chamber; a substrate support that is disposed in the chamber; a gas supply configured to supply a processing gas into the chamber; a first power supply configured to supply a source RF signal to the chamber to form plasma from the processing gas in the chamber; a second power supply configured to supply a bias signal to the substrate support; and a controller (i.e., processing circuitry), in which the controller executes plasma processing in which a cycle including a first period, a second period, a third period, and a fourth period in this order is repeated, controls the first power supply such that the source RF signal has a first power level in the first period, has a second power level that is smaller than the first power level and larger than a zero power level in the second period, has a third power level that is smaller than the first power level and larger than the zero power level in the third period, and has a fourth power level that is smaller than the first power level and larger than the zero power level in the fourth period, and controls the second power supply such that the bias signal has a fifth power level that is larger than the zero power level in the second period, and has a sixth power level that is larger than the fifth power level in the fourth period.

In one exemplary embodiment, the bias signal has the zero power level in the third period.

In one exemplary embodiment, the bias signal has the zero power level in the first period.

In one exemplary embodiment, the cycle has a period in a range of 100 μs to 10000 μs.

In one exemplary embodiment, in the plasma processing, the substrate support has a temperature in a range of 100° C. to 200° C.

In one exemplary embodiment, the bias signal is an RF signal or a direct current voltage pulse signal.

In one exemplary embodiment, the direct current voltage pulse signal has a sequence of voltage pulses having a negative polarity voltage level.

In one exemplary embodiment, the plasma processing includes substrate processing of etching a silicon-containing film through an opening portion of a mask. Throughout the disclosure, a “film” is the same as a “layer.”

In one exemplary embodiment, the silicon-containing film is at least one selected from a silicon oxide film and a silicon nitride film.

In one exemplary embodiment, the mask is at least one selected from a silicon film, a silicon nitride film, a silicon oxide film, a metal-containing film, and an organic film.

In one exemplary embodiment, the processing gas includes a gas containing carbon and fluorine.

In one exemplary embodiment, the chamber includes an upper electrode that is disposed above the substrate support, and the source RF signal is supplied to the upper electrode.

In an exemplary embodiment, a plasma processing method is provided, including (a) providing a substrate having a silicon-containing film and a mask including an opening portion, which is formed on the silicon-containing film, on a substrate support disposed in a chamber; and (b) supplying a processing gas including a gas containing carbon and fluorine into the chamber and forming plasma, in which the (b) includes (b-1) supplying a source RF signal having a first power level to the chamber to deposit a protective film on a surface of the silicon-containing film and a surface of the mask, in which a thickness of the protective film deposited on the surface of the mask is larger than a thickness of the protective film deposited on the surface of the silicon-containing film, (b-2) supplying the source RF signal having a second power level smaller than the first power level and larger than a zero power level to the chamber and supplying a bias signal having a third power level larger than the zero power level to the substrate support to remove the protective film on the surface of the silicon-containing film and to reform the protective film on the surface of the mask, (b-3) stopping the supply of the bias signal to the substrate support, and (b-4) supplying the bias signal having a fourth power level larger than the third power level to the substrate support to etch the silicon-containing film, and a cycle including the (b-1), the (b-2), the (b-3), and the (b-4) in this order is repeated.

In one exemplary embodiment, in the (b-3) and the (b-4), the source RF signal having a power level smaller than the first power level and larger than the zero power level is supplied to the chamber.

In one exemplary embodiment, in the (b-1), the supply of the bias signal to the substrate support is stopped.

In one exemplary embodiment, the cycle has a period in a range of 100 μs to 10000 μs.

In one exemplary embodiment, in the (b), the substrate support has a temperature in a range of 100° C. to 200° C.

In one exemplary embodiment, the mask includes at least one selected from a silicon film, a silicon nitride film, a silicon oxide film, a metal-containing film, and an organic film.

In one exemplary embodiment, the chamber includes an upper electrode that is disposed above the substrate support, and the source RF signal is supplied to the upper electrode.

In one exemplary embodiment, the silicon-containing film is at least one selected from a silicon oxide film and a silicon nitride film.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Example of Plasma Processing System

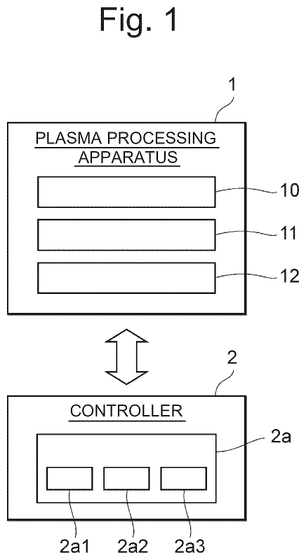

FIG. 1 is a diagram for describing a configuration example of a plasma processing system. In an embodiment, the plasma processing system includes a plasma processing apparatus 1 and a controller 2. The plasma processing system is an example of a substrate processing system, and a plasma processing apparatus 1 is an example of a substrate processing apparatus. The plasma processing apparatus 1 includes a plasma processing chamber (also simply referred to as a “chamber”) 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20 which is described later, and the gas exhaust port is connected to an exhaust system 40 which is described later. The substrate support 11 is disposed in the plasma processing space and has a substrate support surface for supporting a substrate. The chamber 10 may include the substrate support 11.

The plasma generator 12 is configured to form plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 KHz to 10 GHz. Therefore, the AC signal includes a radio frequency (RF) signal and a microwave signal. In an embodiment, the RF signal has a frequency in the range of 100 KHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or the entirety of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

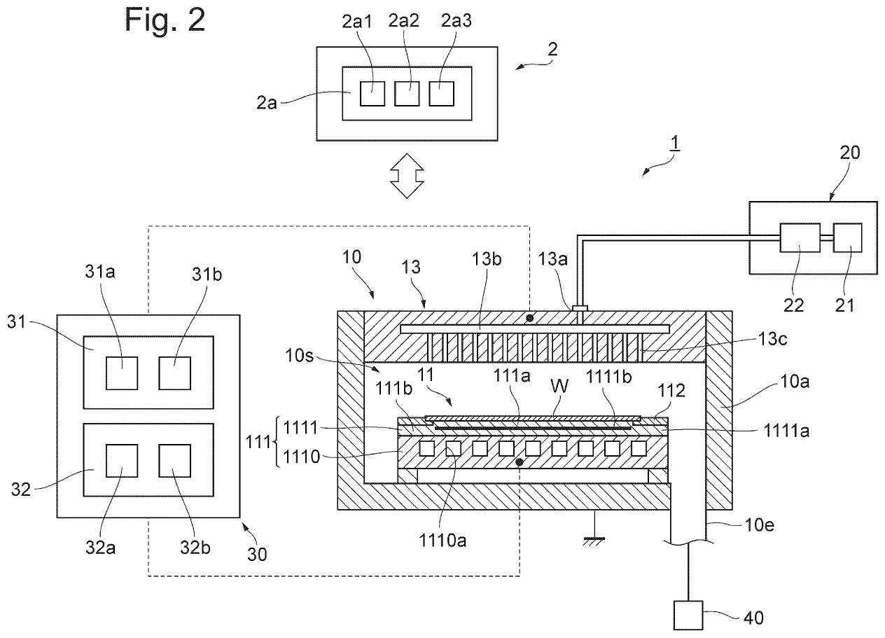

Hereinafter, a configuration example of the capacitively coupled plasma processing apparatus as an example of the plasma processing apparatus 1 will be described. FIG. 2 is a diagram for describing a configuration example of the capacitively coupled plasma processing apparatus.

The capacitively coupled plasma processing apparatus 1 includes the plasma processing chamber 10, the gas supply 20, the power supply system 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply system 30 includes the RF power supply 31 that is coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate a plurality of source RF signals having different frequencies. The generated one or plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency smaller than the frequency of the source RF signal. In an embodiment, the bias RF signal has a frequency in a range of 100 kHz to 60 MHz. In an embodiment, the second RF generator 31b may be configured to generate a plurality of bias RF signals having different frequencies. The generated one or plurality of bias RF signals is supplied to at least one lower electrode. In addition, in various embodiments, at least one of the source RF signal and the bias RF signal may be pulsed.

In addition, the power supply system 30 may include the DC power supply 32 that is coupled to the plasma processing chamber 10. The DC power supply 32 includes a first DC generator 32a and a second DC generator 32b. In an embodiment, the first DC generator 32a is connected to at least one lower electrode, and is configured to generate a first DC signal. The generated first DC signal is applied to at least one lower electrode. The first DC signal may be a bias signal for generating a bias potential that draws ions in the plasma to the substrate support 11. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of positively-polarized voltage pulses and one or a plurality of negatively-polarized voltage pulses in one cycle. The first and second DC generators 32a and 32b may be provided in addition to the RF power supply 31, and the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. A pressure in the plasma processing space 10s is regulated by the pressure regulating valve. The vacuum pump may include a turbo molecular pump, a dry pump, or a combination thereof.

### First Embodiment

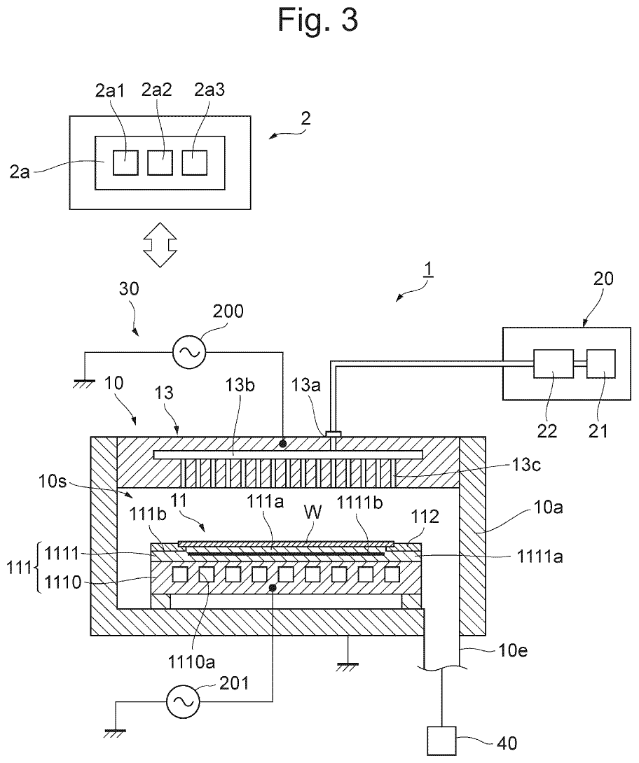

As illustrated in FIG. 3, in an embodiment, the plasma processing apparatus 1 may have a first RF power supply 200 and a second RF power supply 201 as the power supply system 30. The plasma processing apparatus 1 illustrated in FIG. 3 is one form of the plasma processing apparatus 1 illustrated in FIG. 2. The first RF power supply 200 and the second RF power supply 201 are an example of the RF power supply 31.

In an embodiment, the first RF power supply 200 is electrically connected to the upper electrode that is a part of the chamber 10, and is configured to generate the source RF signal for plasma formation. In an embodiment, the source RF signal has a frequency in the range of 10 MHz to 150 MHz. The generated first RF signal is supplied to the upper electrode. The plasma is formed from the processing gas supplied into the chamber 10 by supplying the source RF signal to the upper electrode.

In an embodiment, the second RF power supply 201 is electrically connected to the lower electrode and is configured to generate the bias RF signal for bias generation. In an embodiment, the bias RF signal has a frequency in a range of 100 kHz to 60 MHz. The generated bias RF signal is supplied to the lower electrode. By supplying the bias RF signal to the lower electrode, a bias potential is generated on the substrate W, and ion components in the formed plasma can be drawn into the substrate W. The supply of the source RF signal of the first RF power supply 200 and the bias RF signal of the second RF power supply 201 is controlled by the controller 2.

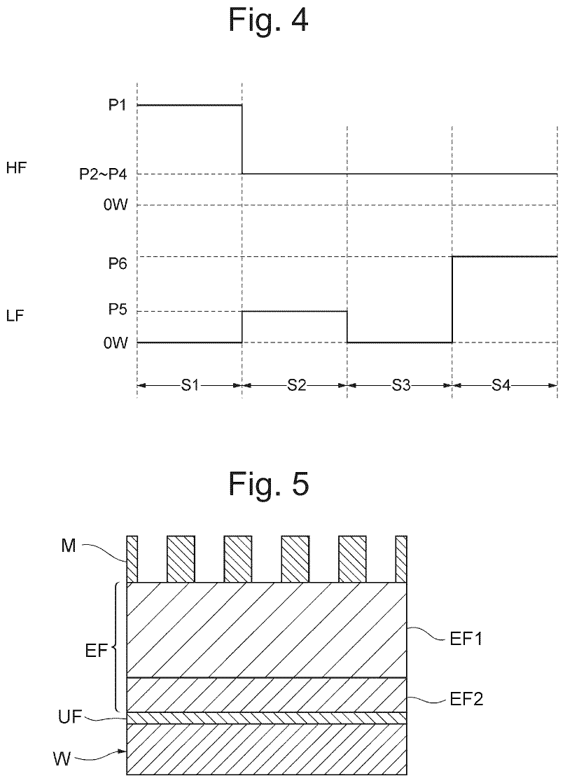

In an embodiment, as illustrated in FIG. 4, the controller 2 executes the plasma processing in which a cycle including a first period S1, a second period S2, a third period S3, and a fourth period S4 in this order is repeated. In an embodiment, each cycle has a period in a range of 100 μs to 10000 μs. In an embodiment, the cycle is repeated a plurality of times for the plasma processing of each substrate W.

In an embodiment, the first RF power supply 200 supplies the source RF signal (HF) to the upper electrode of the chamber 10 in each cycle. The source RF signal has a first power level P1 in the first period S1 of each cycle, a second power level P2 in the second period S2 of each cycle, a third power level P3 in the third period S3 of each cycle, and a fourth power level P4 in the fourth period S4 of each cycle. The power level (W) is an example of a power level.

In an embodiment, the first power level P1 has a power level in a range of 100 W to 500 W. In an embodiment, the second power level P2 is smaller than the first power level P1 and is larger than a zero power level (0 W). In an embodiment, the second power level P2 has a power level in a range of 100 W to 500 W. In an embodiment, the third power level P3 is smaller than the first power level P1 and is larger than the zero power level (0 W). In an embodiment, the third power level P3 may be the same as the second power level P2 or may be smaller than the second power level P2. In an embodiment, the third power level P3 has a power level in a range of 50 W to 300 W. The fourth power level P4 is smaller than the first power level P1 and is larger than the zero power level (0 W). In an embodiment, the fourth power level P4 may be the same as the second power level P2 or may be smaller than the second power level P2. In an embodiment, the fourth power level P4 is the same as the third power level P3. In an embodiment, the fourth power level P4 has a power level in a range of 50 W to 300 W.

In an embodiment, the second RF power supply 201 supplies the bias RF signal (LF) to the lower electrode of the substrate support 11 in each cycle. In an embodiment, the bias RF signal has a fifth power level P5 in the second period S2 of each cycle and has a sixth power level P6 in the fourth period S4 of each cycle. The bias RF signal may have the zero power level (0 W) in the first period S1 and the third period S3.

In an embodiment, the fifth power level P5 is larger than the zero power level (0 W). In an embodiment, the fifth power level P5 has a power level in a range of 10 W to 200 W. In an embodiment, the sixth power level P6 is larger than the fifth power level P5. In an embodiment, the sixth power level P6 has a power level in a range of 100 W to 800 W.

In an embodiment, the second period S2, the third period S3, and the fourth period S4 may be longer than the first period S1. The fourth period S4 may be longer than the second period S2 and the third period S3.

### Example of Plasma Processing

The plasma processing performed using the plasma processing apparatus 1 includes etching processing of etching a film on the substrate W using plasma. The etching processing includes processing of etching the silicon-containing film through the opening portion of the mask on the substrate.

FIG. 5 illustrates an example of the film on the substrate W before the etching processing. A silicon-containing film EF, which is an etched film, is formed on an underlying film UF of the substrate W, and a mask M having a predetermined pattern (opening portion) is formed on a surface of a silicon-containing film EF. The silicon-containing film EF may be at least one selected from a silicon oxide film or a silicon nitride film. The silicon-containing film EF may be a single layer or may be a plurality of layers. The silicon-containing film EF may include a silicon oxide film EF1 and a silicon nitride film EF2. The silicon oxide film EF1 may be formed under the mask M and formed on the silicon nitride film EF2. The mask M may be at least one selected from a silicon film, a silicon nitride film, a silicon oxide film, a metal-containing film, or an organic film. The underlying film UF may be an oxide film. The underlying film UF may be a single layer or a plurality of layers.

In an embodiment, the plasma processing is executed by the controller 2. First, a temperature of a support surface of the substrate support 11 is set and maintained in a range of 100° C. to 200° C. A temperature of the substrate supported on the support surface of the substrate support 11 may be set and maintained in a range of 100° C. to 200° C. The substrate W is transported into the chamber 10 by a transport arm, placed on the substrate support 11 by a lifter, and is held by suction on the substrate support 11 as illustrated in FIG. 3.

Next, the processing gas is supplied to the shower head 13 by the gas supply 20, and is supplied from the shower head 13 to the plasma processing space 10s. The processing gas supplied at this time includes a gas that generates an active species required for the etching processing of the substrate W. The processing gas may contain a CF-based gas containing carbon and fluorine. The CF-based gas may be at least one selected from a fluorocarbon gas and a hydrofluorocarbon gas. The fluorocarbon gas may be at least one selected from the group consisting of CF₄ gas, C₂F₂ gas, C₂F₄ gas, C₃F₆ gas, CsF₈ gas, C₄F₆ gas, C₄F₈ gas, and C₅F₈ gas, as an example. The hydrofluorocarbon gas may be at least one selected from the group consisting of CHF₃ gas, CH₂F₂ gas, CH₃F gas, C₂HF₅ gas, and hydrofluorocarbon gases (C₃H₂F₄ gas, C₃H₂F₆ gas, C₄H₂F₆ gas, and the like) containing three or more C's.

In an embodiment, the source RF signal is supplied to the upper electrode of the chamber 10 by the first RF power supply 200. The bias RF signal is supplied to the lower electrode by the second RF power supply 201. In this case, the atmosphere in the plasma processing space 10s is exhausted from the gas exhaust port 10e, and the inside of the plasma processing space 10s may be depressurized to a predetermined pressure. Plasma is formed in the plasma processing space 10s, and the substrate W is subjected to the etching processing.

In an embodiment, as illustrated in FIG. 4, in the first period S1 in the plasma processing, the first RF signal (HF) having the first power level P1 is supplied to the upper electrode (ON state). In an embodiment, the bias RF signal (LF) has the zero power level (0 W), and the supply of the bias RF signal is stopped (OFF state).

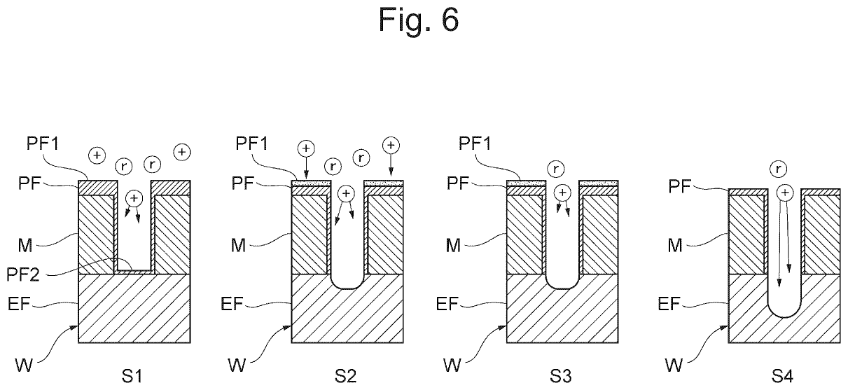

FIG. 6 is an explanatory view describing an example of a state of the film on the substrate in the first period S1, the second period S2, the third period S3, and the fourth period S4. In an embodiment, in the first period S1, ions or radicals generated from the CF-based gas included in the processing gas are deposited on the surface of the mask M on the substrate W or the surface of the silicon-containing film EF (silicon oxide film EF1) to form the protective film PF. A thickness of the protective film PF1 deposited on the surface of the mask film MF is larger than a thickness of the protective film PF2 deposited on the surface of the silicon-containing film EF.

In an embodiment, in the second period S2 in the plasma processing, as illustrated in FIG. 4, the source RF signal (HF) having the second power level P2 is supplied to the upper electrode (ON state), and the bias RF signal (LF) having the fifth power level P5 is supplied to the lower electrode (ON state). In an embodiment, the second power level P2 is smaller than the first power level P1.

In an embodiment, in the second period S2, as illustrated in FIG. 6, the generation of ions or radicals is suppressed as compared with the first period S1, and ions are drawn to a substrate W side. As a result, the protective film PF2 formed on the surface of the silicon-containing film EF on the substrate W is removed, and the protective film PF1 formed on the surface of the mask M is reformed. In an embodiment, the protective film PF1 on the surface of the mask M is reformed by increasing the ratio of C—C bonds in the film. In an embodiment, as the second power level P2 decreases and the fifth power level P5 increases, the removal of the silicon-containing film EF is promoted, and the reforming of the protective film PF is promoted. In addition, as the second power level P2 increases, the formation of the protective film PF is promoted.

In an embodiment, in the third period S3 in the plasma processing, as illustrated in FIG. 4, the source RF signal (HF) having the third power level P3 is supplied to the upper electrode (ON state). In an embodiment, the bias RF signal (LF) has the zero power level (0 W), and the supply of the bias RF signal is stopped (OFF state). In an embodiment, the third power level P3 is smaller than the first power level P1.

In an embodiment, in the third period S3, as illustrated in FIG. 6, the generation of ions or radicals is suppressed as compared with the first period S1. In addition, the temperature of the ions is lowered.

In an embodiment, in the fourth period S4 in the plasma processing, as illustrated in FIG. 4, the source RF signal (HF) having the fourth power level P4 is supplied to the upper electrode (ON state). The bias RF signal (LF) having the sixth power level P6 is supplied to the lower electrode (ON state). In an embodiment, the fourth power level P4 is smaller than the first power level P1. In an embodiment, the sixth power level P6 is larger than the fifth power level P5.

In an embodiment, in the fourth period S4, as illustrated in FIG. 6, the ions are drawn perpendicularly to the substrate W side, and the silicon-containing film EF is etched.

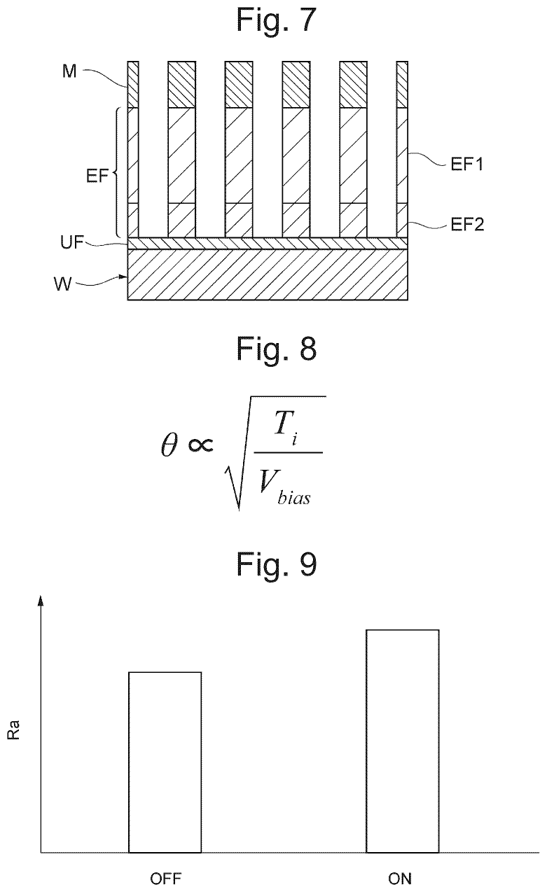

In an embodiment, the cycle of the first period S1 to the fourth period S4 is repeated a predetermined number of times, and for example, as illustrated in FIG. 7, the silicon-containing film EF is etched downward in a hole-like or groove-like shape, and finally, holes or grooves are formed in the silicon oxide film EF1 and the silicon nitride film EF2 of the silicon-containing film EF.

According to the present exemplary embodiment, the plasma processing apparatus 1 is configured such that the controller 2 executes the plasma processing in which the cycle including the first period S1, the second period S2, the third period S3, and the fourth period S4 in this order is repeated, the source RF signal (source RF power) has the first power level P1 in the first period S1, has the second power level P2 in the second period S2, has the third power level P3 in the third period S3, and has the fourth power level P4 in the fourth period S4, and the bias RF signal (bias RF power) has the fifth power level P5 in the second period S2 and has the sixth power level P6 in the fourth period S4. In the second period S2, the protective film PF on the mask M is reformed, whereby the roughness of the film formed by the plasma processing can be reduced.

According to the present exemplary embodiment, in the third period S3, the bias RF signal has the zero power level. As a result, the temperature of the ions in the plasma in the third period S3 decreases. Since an incidence angle θ of the ions into the film on the substrate depends on a temperature Ti of the ions according to the expression illustrated in FIG. 8, the incidence angle θ decreases as the temperature Ti of the ions decreases, and the perpendicularity of the ions drawn into the substrate W is improved. Vbias in the expression of FIG. 8 is a bias potential generated in the substrate support 11.

According to the present exemplary embodiment, in the plasma processing, the substrate support 11 has a temperature in a range of 100° C. to 200° C. As a result, the reforming of the protective film formed on the mask is promoted, and the roughness of the film formed by the plasma processing can be reduced. The temperature of the substrate support 11 may be in a range of 130° C. to 200° C. or in a range of 150° C. to 200° C.

### EXAMPLES

In the second period S2 in the plasma processing, the ratio (Ra) of the C—C bonds (carbon bonds) in the protective film on the mask in a case where the bias RF signal (LF) having the fifth power level P5 was supplied to the substrate support 11 (ON) was compared with the ratio (Ra) of the C—C bonds in the protective film on the mask in a case where the bias RF signal (LF) was not supplied to the substrate support 11 (OFF). FIG. 9 is a graph illustrating the results of such comparison. As illustrated in FIG. 9, the ratio (Ra) of C—C bonds was increased in a case where the bias RF signal was supplied (ON) as compared with a case where the bias RF signal was not supplied (OFF). As a result, it can be confirmed that the reforming of the protective film is promoted by supplying the bias RF signal to the substrate support 11 in the second period S2.

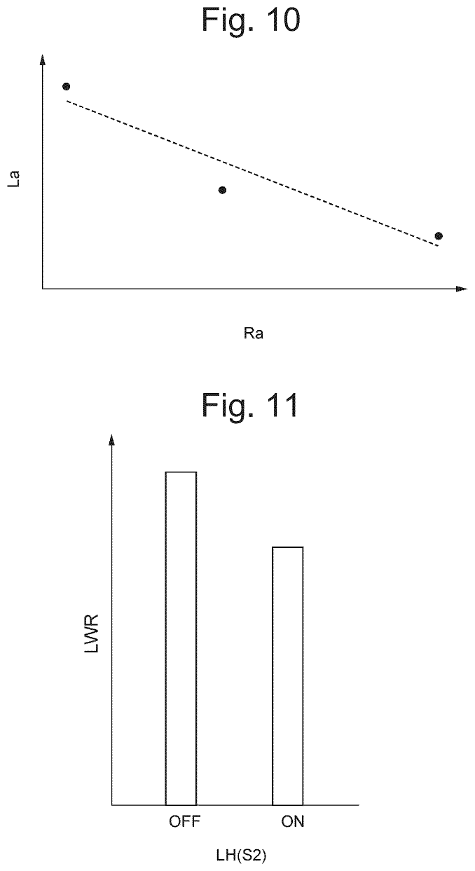

The relationship between the ratio (Ra) of C—C bonds in the protective film on the mask and the lost amount (La) of the protective film by etching was verified. FIG. 10 is a graph illustrating results of such verification. As illustrated in FIG. 10, the loss amount (La) of the protective film was reduced as the ratio (Ra) of the C—C bond in the protective film on the mask was increased. As a result, it can be confirmed that the higher the ratio (Ra) of the C—C bond in the protective film, the higher the etching resistance of the protective film is. As a result, by increasing the ratio (Ra) of the C—C bonds in the protective film, it is possible to reduce scraping of the mask or the etched film by etching, that is, the roughness of the film. In addition, the etching selectivity can be improved.

In the second period S2 in the plasma processing, a line width roughness (LWR) of the finally formed film in a case where the bias RF signal (LH) having the fifth power level P5 is supplied to the substrate support 11 (ON) and the line width roughness (LWR) of the finally formed film in a case where the bias RF signal (LH) is not supplied to the substrate support 11 (OFF) were compared. The line width roughness is indicated by, for example, a variation 3σ (σ: standard deviation) of the line width. FIG. 11 is a graph illustrating results of such comparison. As illustrated in FIG. 11, the line width roughness (LWR) of the film was reduced in a case where the bias RF signal was supplied (ON) as compared with a case where the bias RF signal was not supplied (OFF). As a result, it can be confirmed that the roughness of the film is reduced by supplying the bias RF signal to the substrate support 11 in the second period S2.

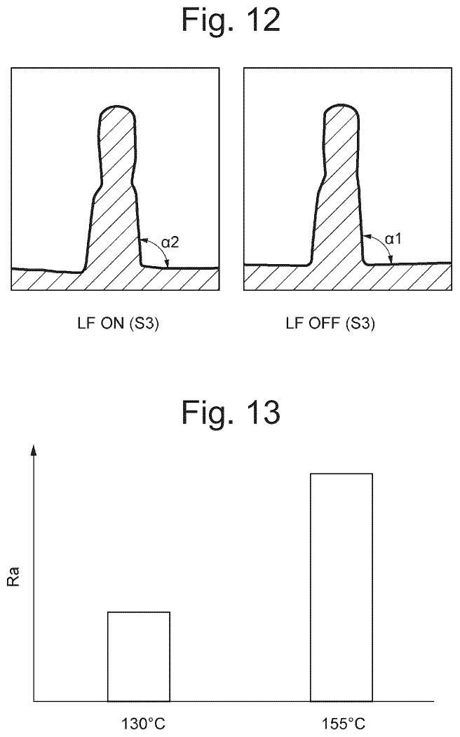

In the third period S3 in the plasma processing, the shape of the finally formed film in a case where the bias RF signal (LH) is not supplied to the substrate support 11 (OFF) and the shape of the finally formed film in a case where the bias RF signal (LH) is supplied to the substrate support 11 (ON) were measured. FIG. 12 illustrates results of such measurement. As illustrated in FIG. 12, an angle α1 of the side wall of the film in a case where the bias RF signal is not supplied to the substrate support 11 (OFF) in the third period S3 is larger than an angle α2 of the side wall of the film in a case where the bias RF signal (LH) is supplied to the substrate support 11 (ON) in the third period S3. It can be confirmed that the perpendicularity of the film shape is improved by not supplying the bias RF signal to the substrate support 11 in the third period S3.

In a case where the temperature of the substrate support 11 in the plasma processing was set to 130° C. and 155° C., the ratio of the C—C bonds in the protective film on the mask was measured and compared. FIG. 13 is a graph illustrating results of such comparison. As illustrated in FIG. 13, when the temperature of the substrate support 11 was increased, the ratio of the C—C bonds in the protective film was increased.

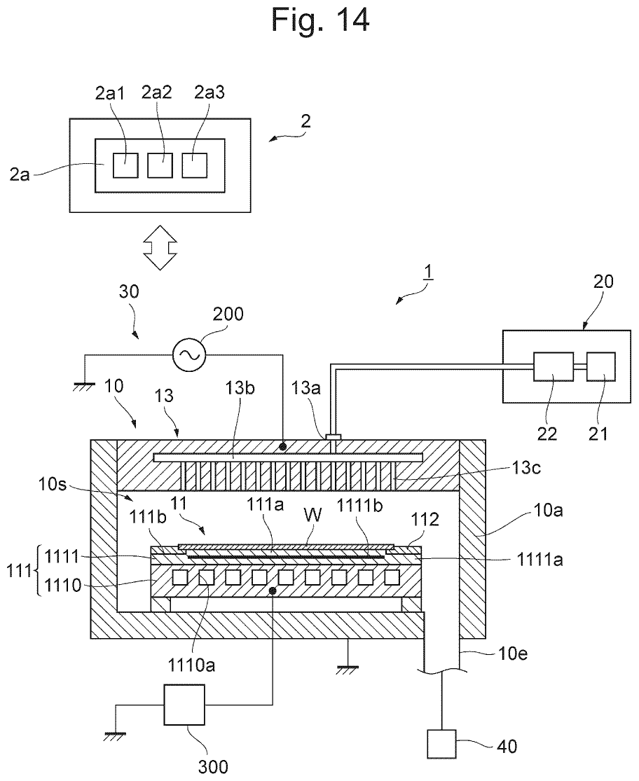

In the above-described embodiment, as illustrated in FIG. 14, the plasma processing apparatus 1 may have a DC power supply 300 as the second power supply instead of the second RF power supply 201. That is, a voltage pulse signal may be supplied to the substrate support 11 instead of the bias RF signal (LF) as the bias signal. Other configurations of the plasma processing apparatus 1 may be the same as those in the above-described embodiment. The DC power supply 300 is an example of the above-described DC power supply 32 illustrated in FIG. 2.

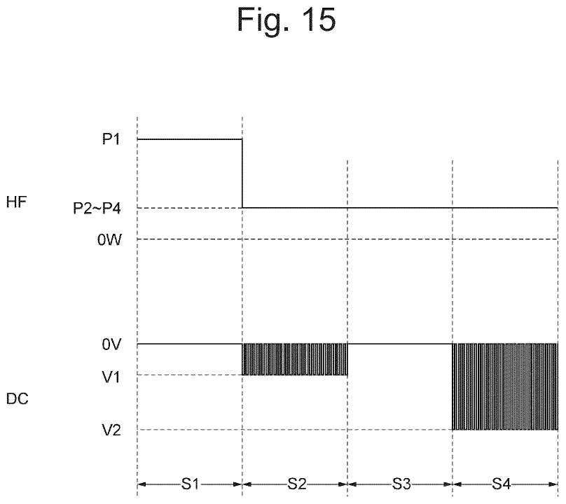

In an embodiment, the DC power supply 300 is electrically connected to the lower electrode of the substrate support 11 and is configured to generate a direct current voltage pulse signal. The generated voltage pulse signal is applied to the lower electrode. As illustrated in FIG. 15, in an embodiment, the voltage pulse signal (DC) acts as the bias signal (bias DC signal). The voltage pulse signal may have a sequence of voltage pulses having a first voltage level V1 in the second period S2 in each cycle and having a second voltage level V2 in the fourth period S4 in each cycle in the plasma processing. The voltage pulse signal may have a zero voltage level in the first period S1 and the third period S3 in each cycle. The voltage level (V) is an example of a power level.

In an embodiment, the sequence of the voltage pulses has a pulse frequency in a range of 300 kHz to 600 KHz. An absolute value of the second voltage level V2 may be larger than an absolute value of the first voltage level V1. In an embodiment, the first voltage level V1 and the second voltage level V2 may have negative polarity. The supply of the source RF signal (HF) and the power level may be the same as those in the above-described embodiment illustrated in FIG. 4.

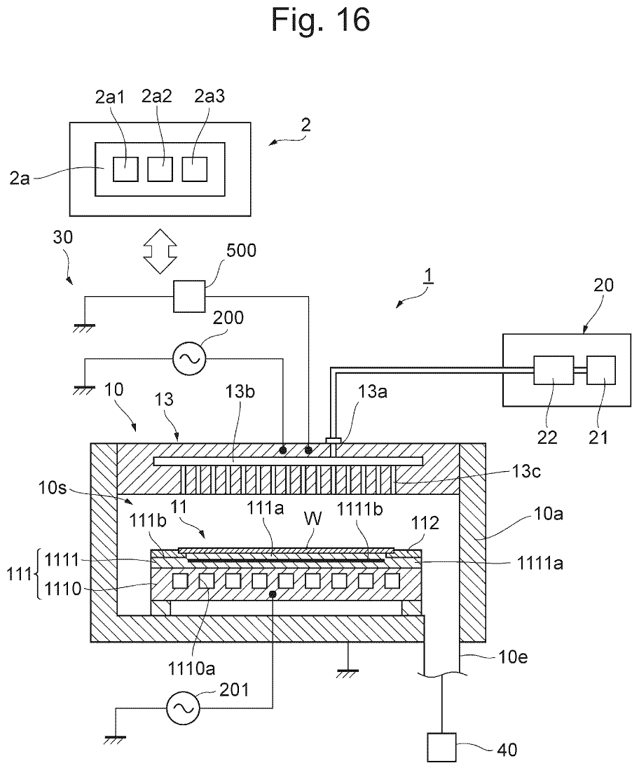

In the above-described embodiment, as illustrated in FIG. 16, the plasma processing apparatus 1 may include an upper DC power supply 500 in addition to the first RF power supply 200, the second RF power supply 201, or the DC power supply 300. In an embodiment, the DC power supply 500 is an example of the above-described DC power supply 32 illustrated in FIG. 2.

In an embodiment, the upper DC power supply 500 is coupled to the upper electrode of the chamber 10 and is configured to generate a direct current upper DC signal. The generated upper DC signal is supplied to the upper electrode of the chamber 10. The upper DC signal may have a negative polarity and may have a negative voltage level. In an embodiment, the upper DC signal may be pulsed. The pulse signal of the upper DC signal may have a rectangular voltage pulse waveform. The upper DC signal may be supplied to the upper electrode in the first period S1 and the second period S2 in the plasma processing. The upper DC signal may be supplied to the upper electrode in the third period S3 and the fourth period S4 in the plasma processing.

By supplying the upper DC signal to the upper electrode, a self-bias voltage of the upper electrode can be increased in an embodiment, and the sputtering effect on the surface of the upper electrode can be increased. In an embodiment, by supplying the upper DC signal to the upper electrode, electrons generated in the upper electrode can be irradiated to the substrate W. In an embodiment, a plasma potential can be controlled. In an embodiment, by supplying the upper DC signal to the upper electrode, an electron density of the plasma can be increased.

For example, in the embodiments described above, while the capacitively coupled plasma apparatus is illustratively described, the present disclosure is not limited thereto, and may be applied to other plasma apparatuses. For example, an inductively coupled plasma apparatus may be used instead of the capacitively coupled plasma apparatus. In this case, the inductively coupled plasma apparatus includes an antenna and a lower electrode. The lower electrode is disposed in the substrate support, and the antenna is disposed on the upper portion of or above the chamber. In an embodiment, the first RF power supply 200 is electrically connected to the antenna, and the second RF power supply 201 is electrically connected to the lower electrode. The DC power supply 300 may be applied instead of the second RF power supply 201. As described above, the first RF power supply 200 is electrically connected to the upper electrode of the capacitively coupled plasma apparatus or the antenna of the inductively coupled plasma apparatus. That is, the first RF power supply 200 is coupled to the plasma processing chamber 10.

The embodiments of the present disclosure further include the following aspects.
(Addendum 1)

A plasma processing apparatus including:
a chamber;
a substrate support that is disposed in the chamber;
a gas supply configured to supply a processing gas into the chamber;
a first power supply configured to supply a source RF signal to the chamber to form plasma from the processing gas in the chamber;
a second power supply configured to supply a bias signal to the substrate support; and
a controller, in which
the controller
   executes plasma processing in which a cycle including a first period, a second period, a third period, and a fourth period in this order is repeated,
   controls the first power supply such that the source RF signal has a first power level in the first period, has a second power level that is smaller than the first power level and larger than a zero power level in the second period, has a third power level that is smaller than the first power level and larger than the zero power level in the third period, and has a fourth power level that is smaller than the first power level and larger than the zero power level in the fourth period, and
   controls the second power supply such that the bias signal has a fifth power level that is larger than the zero power level in the second period, and has a sixth power level that is larger than the fifth power level in the fourth period.
(Addendum 2)

The plasma processing apparatus according to Addendum 1, in which the bias signal has the zero power level in the third period.
(Addendum 3)

The plasma processing apparatus according to Addendum 1 or 2, in which the bias signal has the zero power level in the first period.
(Addendum 4)

The plasma processing apparatus according to any one of Addenda 1 to 3, in which the cycle has a period in a range of 100 μs to 10000 μs.
(Addendum 5)

The plasma processing apparatus according to any one of Addenda 1 to 4, in which, in the plasma processing, the substrate support has a temperature in a range of 100° C. to 200° C.
(Addendum 6)

The plasma processing apparatus according to any one of Addenda 1 to 5, in which the bias signal is an RF signal or a direct current voltage pulse signal.
(Addendum 7)

The plasma processing apparatus according to Addendum 6, in which the direct current voltage pulse signal has a sequence of voltage pulses having a negative polarity voltage level.
(Addendum 8)

The plasma processing apparatus according to any one of Addenda 1 to 7, in which the plasma processing includes substrate processing of etching a silicon-containing film through an opening portion of a mask.
(Addendum 9)

The plasma processing apparatus according to Addendum 8, in which the silicon-containing film is at least one selected from a silicon oxide film and a silicon nitride film.
(Addendum 10)

The plasma processing apparatus according to Addendum 8 or 9, in which the mask is at least one selected from a silicon film, a silicon nitride film, a silicon oxide film, a metal-containing film, and an organic film.
(Addendum 11)

The plasma processing apparatus according to any one of Addenda 1 to 10, in which the processing gas includes a gas containing carbon and fluorine.
(Addendum 12)

The plasma processing apparatus according to any one of Addenda 1 to 11, in which
the chamber includes an upper electrode that is disposed above the substrate support, and
the source RF signal is supplied to the upper electrode.
(Addendum 13)

A plasma processing method including:
(a) providing a substrate having a silicon-containing film and a mask including an opening portion, which is formed on the silicon-containing film, on a substrate support disposed in a chamber; and
(b) supplying a processing gas including a gas containing carbon and fluorine into the chamber and forming plasma, in which
the (b) includes
   (b-1) supplying a source RF signal having a first power level to the chamber to deposit a protective film on a surface of the silicon-containing film and a surface of the mask, in which a thickness of the protective film deposited on the surface of the mask is larger than a thickness of the protective film deposited on the surface of the silicon-containing film,
   (b-2) supplying the source RF signal having a second power level smaller than the first power level and larger than a zero power level to the chamber and supplying a bias signal having a third power level larger than the zero power level to the substrate support to remove the protective film on the surface of the silicon-containing film and to reform the protective film on the surface of the mask,
   (b-3) stopping the supply of the bias signal to the substrate support, and
   (b-4) supplying the bias signal having a fourth power level larger than the third power level to the substrate support to etch the silicon-containing film, and
a cycle including the (b-1), the (b-2), the (b-3), and the (b-4) in this order is repeated.
(Addendum 14)

The plasma processing method according to Addendum 13, in which, in the (b-3) and the (b-4), the source RF signal having a power level smaller than the first power level and larger than the zero power level is supplied to the chamber.
(Addendum 15)

The plasma processing method according to Addendum 13 or 14, in which, in the (b-1), the supply of the bias signal to the substrate support is stopped.
(Addendum 16)

The plasma processing method according to any one of Addenda 13 to 15, in which the cycle has a period in a range of 100 μs to 10000 μs.
(Addendum 17)

The plasma processing method according to any one of Addenda 13 to 16, in which, in the (b), the substrate support has a temperature in a range of 100° C. to 200° C.
(Addendum 18)

The plasma processing method according to any one of Addenda 13 to 17, in which the mask includes at least one selected from a silicon film, a silicon nitride film, a silicon oxide film, a metal-containing film, and an organic film.
(Addendum 19)

The plasma processing method according to any one of Addenda 13 to 18, in which
the chamber includes an upper electrode that is disposed above the substrate support, and
the source RF signal is supplied to the upper electrode.
(Addendum 20)

The plasma processing method according to any one of Addenda 13 to 19, in which the silicon-containing film is at least one selected from a silicon oxide film and a silicon nitride film.

Each of the above embodiments is described for the purpose of description, and it is not intended to limit the scope of the present disclosure. Each of the above embodiments may be reformed in various ways without departing from the scope and gist of the present disclosure. For example, some constitutional elements in one embodiment are able to be added to other embodiments. In addition, some configuration elements in one embodiment are able to be replaced with corresponding configuration elements in another embodiment.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112 (f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

According to one exemplary embodiment of the present disclosure, it is possible to provide a technique for reducing the roughness of a film formed by plasma processing.

What is claimed is:

1. A plasma processing apparatus comprising:
a chamber;
a substrate support that is disposed in the chamber;
a gas supply configured to supply a processing gas into the chamber;
a first power supply configured to supply a source RF signal to the chamber to form plasma from the processing gas in the chamber;
a second power supply configured to supply a bias signal to the substrate support; and
processing circuitry, wherein
the processing circuitry is configured to
execute plasma processing in which a cycle including a first period, a second period, a third period, and a fourth period in this order is repeated,
control the first power supply such that the source RF signal has a first power level in the first period, has a second power level that is smaller than the first power level and larger than a zero power level in the second period, has a third power level that is smaller than the first power level and larger than the zero power level in the third period, and has a fourth power level that is smaller than the first power level and larger than the zero power level in the fourth period, and
control the second power supply such that the bias signal has a fifth power level that is larger than the zero power level in the second period, and has a sixth power level that is larger than the fifth power level in the fourth period.

2. The plasma processing apparatus according to claim 1, wherein the bias signal has the zero power level in the third period.

3. The plasma processing apparatus according to claim 1, wherein the bias signal has the zero power level in the first period.

4. The plasma processing apparatus according to claim 1, wherein the cycle has a period in a range of 100 μs to 10000 μs.

5. The plasma processing apparatus according to claim 1, wherein in the plasma processing, the substrate support has a temperature in a range of 100° C. to 200° C.

6. The plasma processing apparatus according to claim 1, wherein the bias signal is an RF signal or a direct current voltage pulse signal.

7. The plasma processing apparatus according to claim 6, wherein the direct current voltage pulse signal has a sequence of voltage pulses having a negative polarity voltage level.

8. The plasma processing apparatus according to claim 1, wherein the plasma processing includes substrate processing of etching a silicon-containing layer through an opening portion of a mask.

9. The plasma processing apparatus according to claim 8, wherein the silicon-containing layer is at least one selected from a silicon oxide layer and a silicon nitride layer.

10. The plasma processing apparatus according to claim 8, wherein the mask is at least one selected from a silicon layer, a silicon nitride layer, a silicon oxide layer, a metal-containing layer, and an organic layer.

11. The plasma processing apparatus according to claim 1, wherein the processing gas includes a gas containing carbon and fluorine.

12. The plasma processing apparatus according to claim 1, wherein
the chamber includes an upper electrode that is disposed above the substrate support, and
the source RF signal is supplied to the upper electrode.

13. A plasma processing method comprising:
(a) providing a substrate on a substrate support disposed in a chamber; the substrate having a silicon-containing layer and a mask including an opening portion, the mask formed on the silicon-containing layer; and
(b) supplying a processing gas including a gas containing carbon and fluorine into the chamber and forming plasma, wherein
the (b) includes
(b-1) supplying a source RF signal having a first power level to the chamber to deposit a protective layer on a surface of the silicon-containing layer and a surface of the mask, a thickness of the protective layer deposited on the surface of the mask is larger than a thickness of the protective layer deposited on the surface of the silicon-containing layer,
(b-2) supplying the source RF signal having a second power level smaller than the first power level and larger than a zero power level to the chamber and supplying a bias signal having a third power level larger than the zero power level to the substrate support to remove the protective layer on the surface of the silicon-containing layer and to reform the protective layer on the surface of the mask,
(b-3) stopping the supply of the bias signal to the substrate support, and
(b-4) supplying the bias signal having a fourth power level larger than the third power level to the substrate support to etch the silicon-containing layer, and
a cycle including the (b-1), the (b-2), the (b-3), and the (b-4) in this order is repeated.

14. The plasma processing method according to claim 13, wherein in the (b-3) and the (b-4), supplying the source RF signal having a power level smaller than the first power level and larger than the zero power level to the chamber.

15. The plasma processing method according to claim 13, wherein in the (b-1), stopping the supply of the bias signal to the substrate support.

16. The plasma processing method according to claim 13, wherein the cycle has a period in a range of 100 μs to 10000 μs.

17. The plasma processing method according to claim 13, wherein in the (b), the substrate support has a temperature in a range of 100° C. to 200° C.

18. The plasma processing method according to claim 13, wherein the mask includes at least one selected from a silicon layer, a silicon nitride layer, a silicon oxide layer, a metal-containing layer, and an organic layer.

19. The plasma processing method according to claim 13, wherein
the chamber includes an upper electrode that is disposed above the substrate support, and
the source RF signal is supplied to the upper electrode.

20. The plasma processing method according to claim 13, wherein the silicon-containing layer is at least one selected from a silicon oxide layer and a silicon nitride layer.
